(19) United States
(12) Patent Application Publication
(10) Pub. No.: US 2001/0008779 A1
(43) Pub. Date: Jul. 19, 2001

(54) Semiconductor device and manufacturing method

(76) Inventors: Yoshinori Miyaki, Tachikawa (JP); Yasuhisa Hagiwara, Higashiyamato (JP); Seiichi Ichihara, Hino (JP); Hisao Nakamura, Akinuno (JP); Hidenori Suzuki, Kodaira (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/805,189

(22) Filed: Mar. 14, 2001

Related U.S. Application Data
(62) Division of application No. 09/741,899, filed on Dec. 22, 2000.

(30) Foreign Application Priority Data
Dec. 24, 1999 (JP) 11-367161

(51) Int. Cl. H01L 29/74; H01L 31/111; H01L 21/44; H01L 21/48; H01L 21/50; H01L 23/495

(52) U.S. Cl. 438/111; 257/668

(57) ABSTRACT

A semiconductor device comprising: a tape substrate which supports a semiconductor chip, said chip having surface electrodes, said tape substrate being provided with a plurality of leads corresponding to the surface electrodes of the semiconductor chip and bonded thereto, and with dummy leads formed in vacant regions in corner portions of the tape substrate where the leads are not formed; conductive members for bonding the surface electrodes of the semiconductor chip to the leads of the tape substrate; and a plurality of external terminals arranged on an outside periphery of the semiconductor chip and mounted on the tape substrate.

### FIELD OF THE INVENTION

The present invention relates to a technology for manufacturing a semiconductor device and, in particular, to a technology effectively applicable to an improvement in the reliability of a semiconductor device of a Fan-Out type using a tape substrate.

### BACKGROUND OF THE INVENTION

The technology described below has been studied by the present inventors when the present invention has been developed and accomplished, and the outline thereof is as follows.

In a semiconductor device having a semiconductor chip in which a semiconductor integrated circuit is formed, a semiconductor package referred to as a CSP (Chip Scale Package, or Chip Size Package) has been known as an example of a structure for reducing its size and providing multiple pins.

This CSP is also referred to as a fine pitch BGA (Ball Grid Array) and is also referred to as a tape fine pitch BGA (hereinafter referred to as T-FBGA (Tape-type Fine-pitch BGA)) because many of them uses a tape substrate made of polyimide tape or the like.

Further, a thin T-FBGA of the T-FBGAs is referred to as a T-TFBGA (Tape-type Thin Fine-pitch BGA). In the case where the T-TFBGA has a Fan-Out type structure, that is, a structure in which solder balls, which are external terminals, are arranged on the outside periphery of a semiconductor chip, the strength (rigidity) or the flatness of the outside peripheral portion of the tape substrate relates to the reliability in bonding of the solder balls as the BGA.

Also, in the T-TFBGA, while the ball lands of the tape substrate on which the solder balls are mounted and the pads (surface electrodes) of the semiconductor chip are bonded to each other by the leads made of a copper foil mounted on the tape substrate, the pattern of the leads has higher density in some places near the corners of the tape substrate. As a result, sometimes, a lead pattern may be formed in a partial region in the corners.

In this connection, the T-TFBGA is disclosed in “Monthly Semiconductor World, Special Issue, ‘99, Semiconductor Manufacturing Inspecting Technology, page 36-41”, by Press Journal Co., Jul. 27, 1998, or also in the Japanese Patent Laid-Open No. 98073/1998.

### SUMMARY OF THE INVENTION

In the above-mentioned T-TFBGA, sometimes, the lead pattern may be arranged in a partial region in the corners of the tape substrate. In this case, there is presented a problem that the stress (thermal stress) generated during a temperature cycle test is intensively applied to the place where the lead pattern is arranged in a partial region and, as a result, breaks the leads in the corners.

An object of the present invention is to provide a semiconductor device capable of reliability and its manufacturing method.

The above-mentioned object, the other objects, and the novel features of the present invention will be clear from the description of the present specification and the accompanying drawings.

The outline of a typical example of the invention disclosed in the present application will be described in brief as follows.

Namely, a semiconductor in accordance with the present invention includes a tape substrate which supports a semiconductor chip, said chip having surface electrodes, said tape substrate being provided with a plurality of leads corresponding to the surface electrodes of the semiconductor chip and bonded thereto, and with dummy leads formed in vacant regions in corner portions of the tape substrate where the leads are not formed; conductive members for bonding the surface electrodes of the semiconductor chip to the leads of the tape substrate; and a plurality of external terminals arranged on an outside periphery of the semiconductor chip and mounted on the tape substrate.

According to the present invention, since the dummy leads are formed in the vacant regions in the corners of the tape substrate where the leads are not formed, the strength of the corners of the tape substrate can be enhanced. This can prevent a break in the leads in the corners of the tape substrate when a temperature cycle test is conducted.

As a result, this can improve the reliability of the semiconductor device.

Also, a method of manufacturing a semiconductor device in accordance with the present invention includes the steps of: preparing a tape substrate having leads and dummy leads, said leads corresponding to surface electrodes of a semiconductor chip and capable of being bonded thereto, and said dummy leads being formed in vacant regions in corner portions of the tape substrate where the leads are not formed; bonding the surface electrodes of the semiconductor chip to the corresponding leads of the tape substrate by conductive parts to support the semiconductor chip by the tape substrate; and mounting a plurality of external terminals on an outside periphery of the semiconductor chip in an external terminal mounting face of the tape substrate, wherein the dummy leads can enhance strength of the corner portions of the tape substrate.

### BRIEF DESCRIPTIONS OF THE DRAWINGS

FIG. 1 is a plan view showing an example of the structure of a semiconductor device in accordance with a first embodiment of the present invention;

FIG. 2 is a bottom view showing the structure of the semiconductor device shown in FIG. 1;

FIG. 3 is a sectional view showing the structure of the cross section taken along the line A-A in FIG. 2;

FIG. 4 is a plan view showing an example of a lead pattern in a tape substrate of the semiconductor device shown in FIG. 1;

FIG. 5 is a partial enlarged plan view showing the detailed structure of a portion B in FIG. 4;

FIG. 6 is a process flowchart showing an example of the manufacturing procedures of a semiconductor device in accordance with the first embodiment of the present invention;

FIG. 7 is a partial side view showing an example of a packaging embodiment of a semiconductor device in accordance with the first embodiment of the present invention;

FIG. 8 is a partial plan view showing an example of a packaging embodiment of a semiconductor device in accordance with the first embodiment of the present invention;

FIG. 9 is a plan view showing an example of a lead pattern in a tape substrate of a semiconductor device in accordance with a second embodiment of the present invention;

FIG. 10 is a partial enlarged plan view showing the detailed structure of a portion C in FIG. 9;

FIG. 11 is a plan view showing an example of the structure of a semiconductor device in accordance with a third embodiment of the present invention;

FIG. 12 is a bottom view showing the structure of the semiconductor device shown in FIG. 11;

FIG. 13 is a sectional view showing the structure of the cross section taken along the line A-A in FIG. 12;

FIG. 14 is a partial enlarged plan view showing an example of a lead pattern in the tape substrate of the semiconductor device shown in FIG. 11; and

FIG. 15 is a partial enlarged plan view showing an example of a lead pattern in a tape substrate of a semiconductor device in accordance with a fourth embodiment of the present invention.

### DESCRIPTION OF THE PREFERRED EMBODIMENTS

The preferred embodiments in accordance with the present invention will be described in detail based on the accompanying drawings. Here, in all the drawings for describing the preferred embodiments, members having like functions are designated by like reference characters and their descriptions will not be repeated.

(First Embodiment)

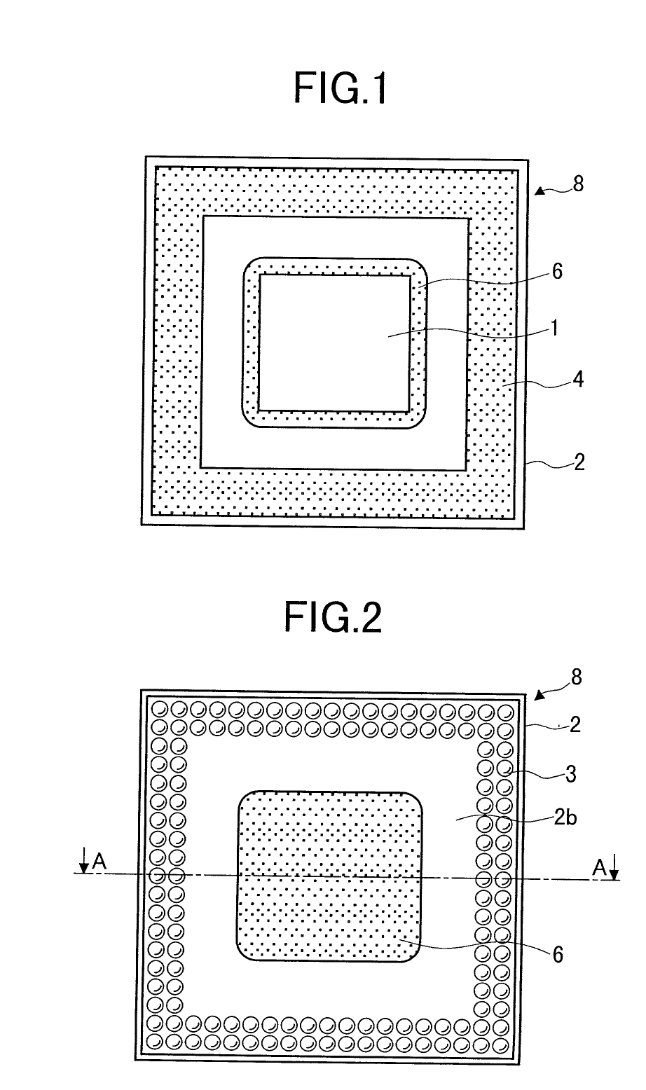

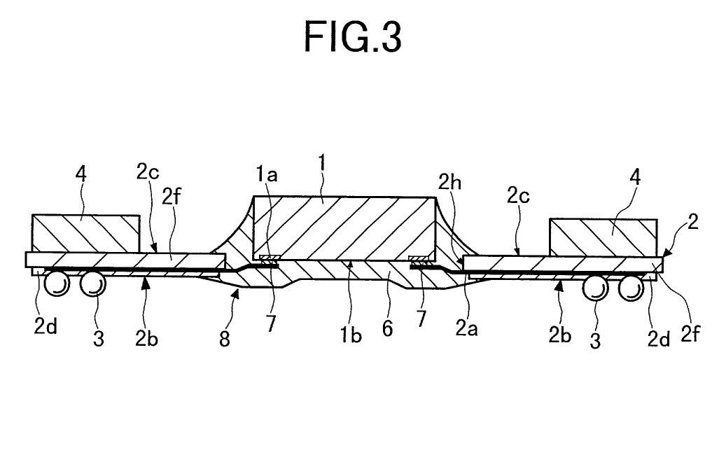

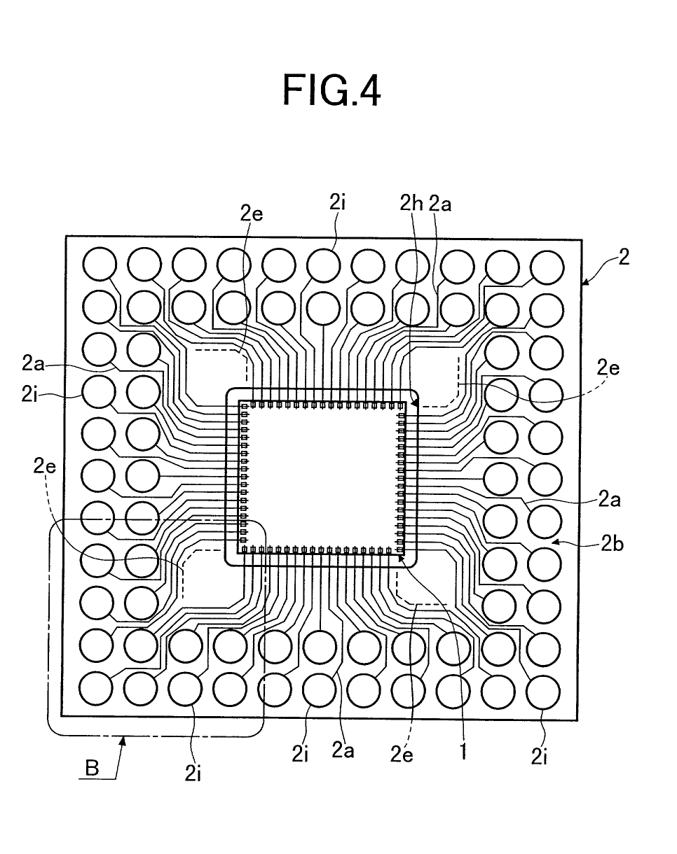

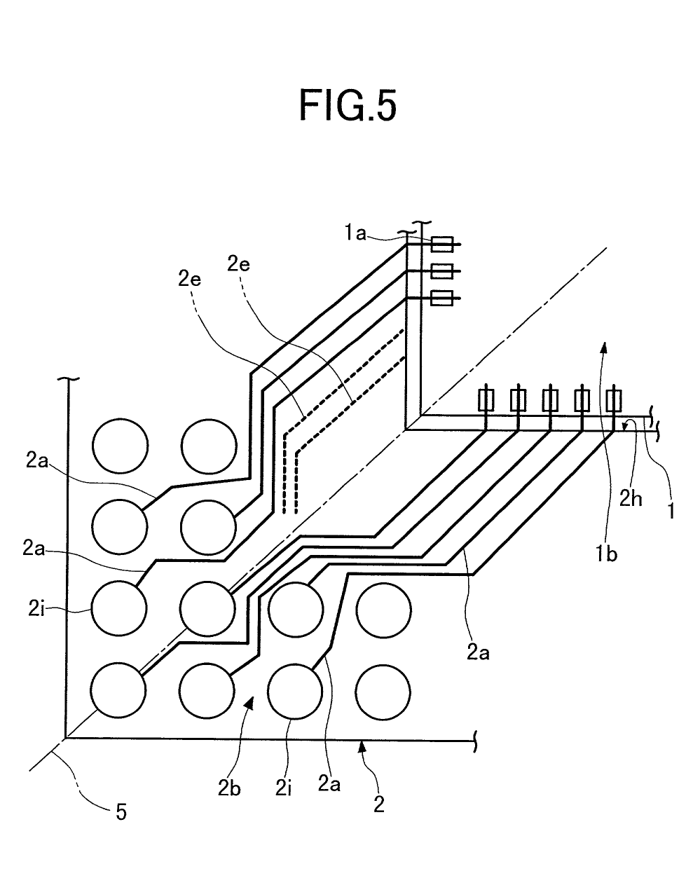

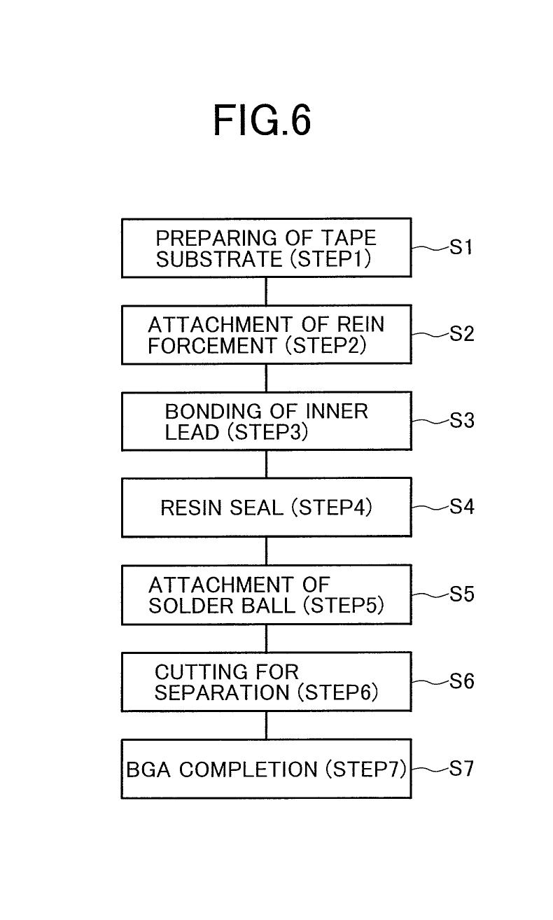

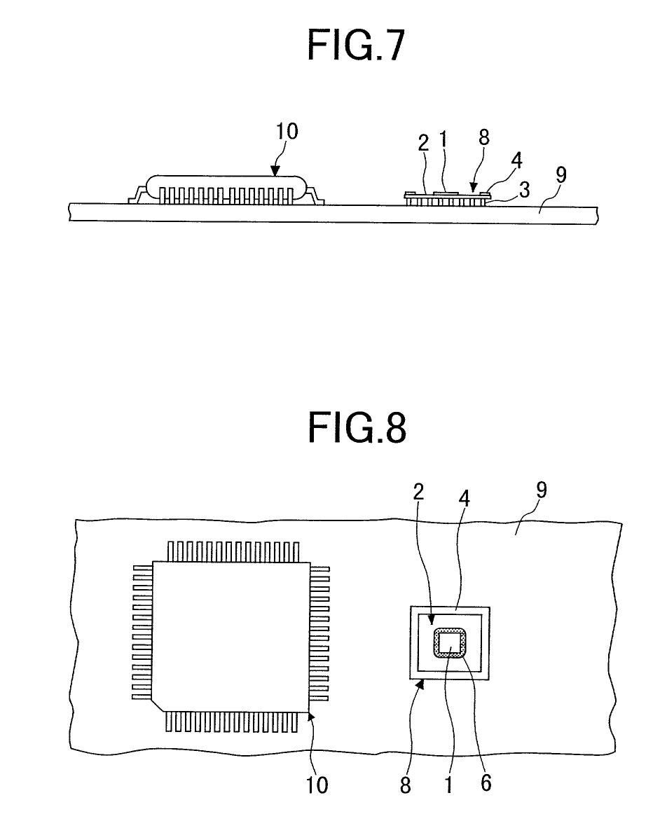

FIG. 1 is a plan view showing an example of the structure of a semiconductor device (T-TFBGA) in accordance with a first embodiment of the present invention. FIG. 2 is a bottom view showing the structure of the semiconductor device shown in FIG. 1. FIG. 3 is a sectional view showing the structure of the cross section taken along the line A-A in FIG. 2. FIG. 4 is a plan view showing an example of a lead pattern in a tape substrate of the semiconductor device shown in FIG. 1. FIG. 5 is a partial enlarged plan view showing the detailed structure of a portion B in FIG. 4. FIG. 6 is a process flowchart showing an example of the manufacturing procedures of a semiconductor device in accordance with the first embodiment of the present invention. FIG. 7 is a partial side view showing an example of a packaging embodiment of a semiconductor device in accordance with the first embodiment of the present invention. FIG. 8 is a partial plan view showing an example of a packaging embodiment of a semiconductor device in accordance with the first embodiment of the present invention.

The semiconductor device in accordance with the first embodiment shown in FIGS. 1 to 3 is a semiconductor package of a fine-pitch type having a relatively large number of pins for its chip size such as a microcomputer, an ASIC (Application Specific Integrated Circuit) or the like, and is a T-TFBGA 8 of a Fan-Out and thin type using a tape substrate 2 and having a plurality of solder balls 3, which are external terminals, on the outside of a semiconductor chip 1.

The constitution of the T-TFBGA 8 will be explained by the use of FIGS. 1 to 5. The T-TFBGA 8 comprises a tape substrate 2 provided with a plurality of leads 2a for supporting the semiconductor chip 1 and corresponding to pads (surface electrodes) 1a of the semiconductor chip 1 and connected thereto; and dummy leads 2e arranged in the corner portions such that the leads 2a are symmetrically arranged with respect to a diagonal line 5; gold bumps 7 which are conductive members for connecting the pads la of the semiconductor chip 1 to the leads 2 of the tape substrate 2; a frame-shaped reinforcing member 4 for reinforcing the tape substrate and attached to a back face 2c which is a face opposite to the external terminal mounting face 2b of the tape substrate 2 on which solder balls 3 are mounted; and a plurality of solder balls 3, which are external terminals, attached to the external terminal mounting face 2b of the tape substrate 2 and arranged on the outside periphery of the semiconductor chip 1, wherein the dummy leads 2e disperse the stress (for example, thermal stress) applied to the corner portions of the tape substrate 2 to the whole regions of the corner portions.

The tape substrate 2 of the T-TFBGA 8 in accordance with the first embodiment is shaped like a square in a plan view, as shown in FIG. 4, and has a plurality of leads 2a, which are wirings and which are formed by placing a copper foil on a film base material 2f formed of a polyimide tape, as shown in FIG. 3.

In the center of the tape substrate 2, as shown in FIG. 4, is formed a square opening 2h in which the semiconductor chip 1 can be arranged, and one ends of the plurality of leads 2a are projected and are connected to the corresponding pads 1a of the semiconductor chip 1 via the gold bumps 7.

Thus, the semiconductor chip 1 is supported by the one ends of the plurality of leads 2a of the tape substrate 2 via the gold bumps 7.

Further, as shown in FIG. 4, the other ends of the respective leads 2a are connected to the ball lands 2i which are terminals on which the solder balls 3 are mounted. Therefore, the ball lands 2i corresponding to the number of external terminals (number of pins) are arranged in an uncovered state on the external terminal mounting face 2b of the tape substrate 2.

As shown in FIG. 3, a solder resist 2d which is an insulating film for protecting and insulating the respective leads 2a are formed on the surface of the external terminal mounting face 2b of the tape substrate 2. Here, though the solder resist 2d covering the respective leads 2a is omitted in FIG. 4 and FIG. 5 in order to clearly illustrate the lead pattern of the external terminal mounting face 2b, the surface of the external terminal mounting face 2b of the tape substrate 2 except for the respective ball lands 2i is covered with the solder resist 2d, as shown in FIG. 3.

Though the number of ball lands 2i shown in FIG. 4 is smaller than that of the solder balls 3 shown in FIG. 2 in order to clearly illustrate the lead pattern, the number of the ball lands 2i shown in FIG. 4 is essentially equal to the number of the solder balls 3 shown in FIG. 2.

In the T-TFBGA 8 of the first embodiment, as shown in FIG. 5, the dummy leads 2e are mounted in the vicinity of the corner portions of the tape substrate 2 such that the lead pattern formed by the wiring of the leads 2a is symmetrically arranged with respect to the diagonal lines 5 of the external terminal mounting face 2b of the tape substrate 2.

Therefore, the lead pattern including the leads 2a and the dummy leads 2e are symmetrically arranged with respect to the diagonal lines 5 of the tape substrate 2 because the dummy leads 2e are formed near the corner portions of the tape substrate 2. As a result, when a thermal stress is applied to the portions near the corner portions of the tape substrate 2 in a temperature cycle test or the like, the thermal stress results in being dispersedly applied to the whole areas near the corner portions of the tape substrate 2.

The dummy leads 2e are formed at all the four corner portions of the tape substrate 2 in the T-TFBGA 8 of the first embodiment, as shown in FIG. 4.

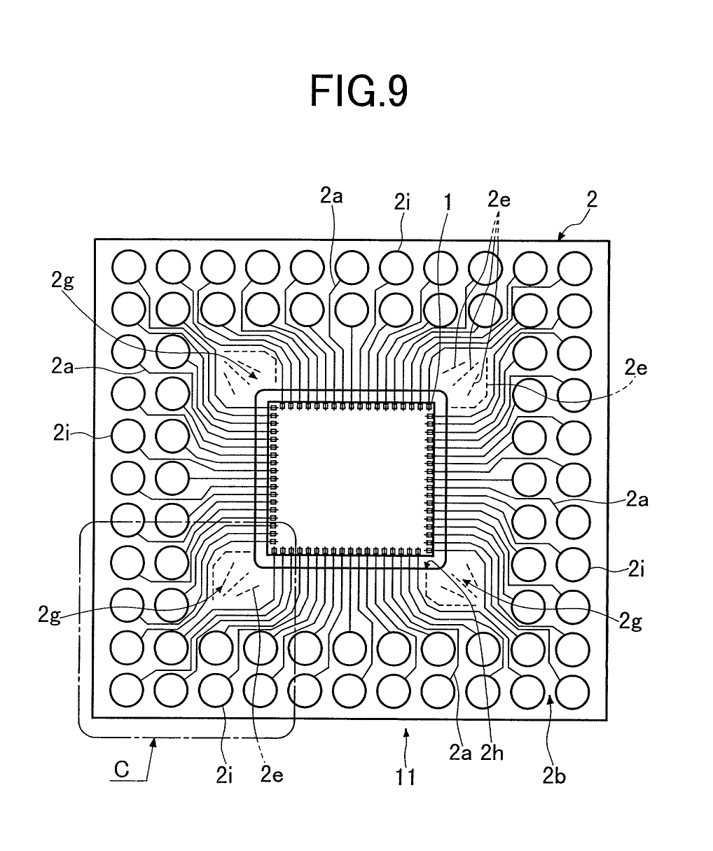

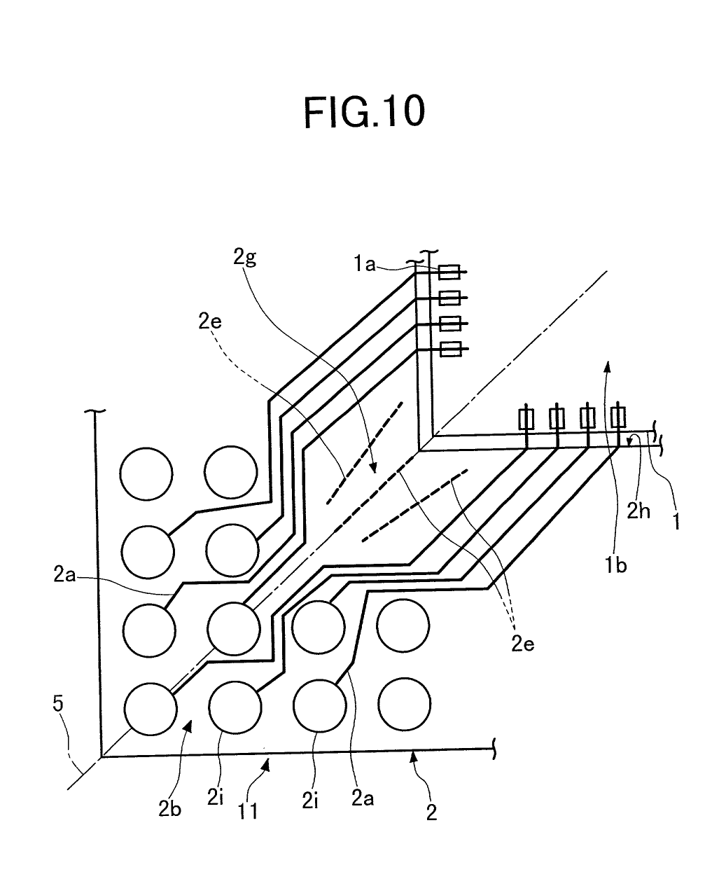

Further, though the leads 2a are illustrated by the solid lines and the dummy leads 2e are illustrated by the dotted lines in FIG. 4 and FIG. 5 in order to make a distinction between the leads 2a and the dummy leads 2e, the actual dummy leads 2e are long thin wirings like the leads 2a (ditto for FIG. 9 and FIG. 10 of a second embodiment described below).

The dummy leads 2e are formed in the same manufacturing process by using a copper foil or the like as is the case with the respective leads 2a. However, both ends of the respective dummy leads 2e are terminated without being connected to the pads 1 and the ball lands 2i of the semiconductor chip 1 and hence do not have the function of transmitting an electric signal.

Therefore, it is desirable that the one ends of semiconductor chip side of the dummy leads 2e are not projected into the opening 2h of the tape substrate 2.

Also, the reinforcing member 4 mounted on the back face 2c of the tape substrate 2, as shown in FIG. 3, reinforces the solder ball mounting portions of the tape substrate 2 to enhance its strength so as to improve the flatness of the T-TFBGA 8, so that the reinforcing member 4 is shaped like a frame as shown in FIG. 1.

Therefore, the reinforcing member 4 is preferably formed of a metal thin plate in order to enhance the strength of the above-mentioned solder ball mounting portions of the tape substrate 2 and, for example, when the T-TFBGA 8 is mounted on a packaging substrate 9 shown in FIG. 7, in order to bring the thermal expansion coefficients of both (packaging substrate 9 and T-TFBGA 8) close to each other, the reinforcing member 4 is preferably formed of a metal thin plate (a thin plate of copper alloy) formed by plating a copper foil with nickel, but it may be formed of the other materials.

This brings the thermal coefficient of the T-TFBGA 8 and that of the packaging substrate 9 close to each other and when the T-TFBGA 8 is mounted on the packaging substrate 9, this can reduce the stress applied to the solder balls 3 connected to both and thus can improve reliability in connection of the solder balls 3.

The gold bumps 7 formed on the pads la of the semiconductor chip 1, as shown in FIG. 3, are formed, for example, by growing gold plating on the pads 1a after a semiconductor integrated circuit is formed in a semiconductor wafer before it is diced, and are terminals for connecting the pads 1a of the semiconductor chip 1 to the leads 2a of the tape substrate 2.

Around the junctions where the semiconductor chip 1 and the leads 2a are bonded to each other via the gold bumps 7 are formed a sealing portion 6 for covering them.

The sealing part 6 is formed, for example, by sealing the semiconductor chip 1 and the projecting portions of the leads 2a with an epoxy-based thermosetting resin for sealing and is formed by potting in the case of the T-TFBGA 8 of the first embodiment.

The sealing part 6, however, is not formed by potting, but may be formed by molding.

The solder balls 3, which are external terminals, mounted on the T-TFGBA 8 are ball-shaped terminals having a diameter of about 0.3 mm, for example, and are further mounted on the respective ball lands 2i of the external terminal mounting face 2b of the tape substrate 2 at narrow pitches because the T-TFBGA 8 is a fine-pitch type.

In FIG. 7 and FIG. 8 will be shown a packaging embodiment in which the T-TFBGA 8 is packaged on a packaging substrate 9. The T-TFBGA 8 can be packaged on the same packaging substrate 9 with a semiconductor device of the other surface packaging type such as a QFP (Quad Flat Package) 10 and the like. Also when it is packaged, it can be packaged with the QFP10 in the same solder reflow process that is the packaging process of the QFP10. In other words, the T-TFBGA 8 can be packaged mixedly with the QFP10 or the like.

Next, the manufacturing method of the semiconductor (T-TFBGA 8) of the first embodiment will be described according to a manufacturing process flowchart shown in FIG. 6.

Here, in the first embodiment will be described a case where individual T-TFBGAs 8 are manufactures by using a long multiple film tape capable of manufacturing a plurality of T-TFBGAs 8.

To begin with, a semiconductor wafer (not shown) is prepared which is mounted with a plurality of semiconductor chips 1 each of which has a desired semiconductor integrated circuit formed on its main surface 1b.

Further, gold bumps 7 (conductive parts) are formed by gold plating on the pads la of the respective semiconductor chips 1 on the semiconductor wafer, with predetermined regions covered with a mask, in the above-mentioned state of the semiconductor wafer.

Then, this semiconductor wafer is diced and separated into individual semiconductor chips 1, and then the individual semiconductor chips 1 are subjected to a predetermined test, and the semiconductor chips 1 which are judged as being good ones are prepared.

On the other hand, a tape substrate 2 is prepared for the respective T-TFBGAs 8, said tape substrate having leads 2a, which are wirings to be connected to the corresponding pads 1a of the semiconductor chip 1, and the dummy leads 2e formed in the corner portions such that the leads 2a are symmetrically arranged with respect to the diagonals 5 (step S1).

Here, a multiple film tape of a polyimide film or the like in which a plurality of tape substrates 2 are connected to each other is prepared.

As a manufacturing procedure of the tape substrate 2, first, a copper foil is placed on the external terminal mounting face 2b side of the film base material 2f, which is the above-mentioned film tape, by the use of an epoxy-based adhesive or the like, and thereafter the copper foil layer is subjected to an etching process to make a predetermined shape, whereby the leads 2a and the dummy leads 2e are formed.

Thereafter, at step S2, a reinforcing member 4 shaped like a frame is placed on the outer peripheral portion of the back face 2c of the tape substrate 2.

Then, an inner lead binding process is performed at step S3.

Here, the gold bumps 7 formed on the pads la of the semiconductor chip 1 are bonded to the corresponding leads 2a by a gang bonding, that is, a collective bonding.

When they are bonded to each other, first, the semiconductor chip 1 is arranged at the opening 2h in the center of the tape substrate 2 and the one ends of the leads 2a arranged at the opening 2h are thermally pressed and bonded to the pads 1a of the semiconductor chip 1 via the gold bumps 7, whereby the pads la of he semiconductor chip 1 are bonded to the corresponding leads 2a of the tape substrate 2 via the gold bumps 7 and the semiconductor chip 1 is supported by the opening 2h of the tape substrate 2 by means of the leads 2a.

In other words, in the inner lead bonding process at step S3, a chip mounting process and a bonding process for bonding the leads 2a of the tape substrate 2 to the pads 1a of the semiconductor chip 1 are performed at the same time.

Thereafter, the semiconductor chip 1, the leads 2a, and the gold bumps 7 are sealed by potting by the use of an epoxy-based thermosetting sealing resin to form a sealing part 6 (step S4).

The sealing part 6 may be molded by the use of the above-mentioned sealing resin.

Then, at step S5, a plurality (a predetermined number) of solder balls 3, which are external terminals, are mounted on the outer periphery of the semiconductor chip 1 in the external terminal mounting face 2b of the tape substrate 2.

When the solder balls 3 are mounted, first, the solder balls 3 are provisionally fixed to the ball lands 2i of the tape substrate 2 by the use of flux and then are passed through a reflow furnace having a peak temperature of about 230° C., for example, to fix the solder balls 3.

Thereafter, at step 6, individual tape substrates 2, that is, individual T-TFBGAs 8 are diced and separated from the multiple film tape and this is the end of the manufacturing process of the individual T-TFBGAs 8 (step S7).

Further, when the T-TFBGA 8 of the first embodiment is packaged on a packaging substrate 9 or the like, it can be packaged on the same packaging substrate 9 with the semiconductor device of the other surface packaging type such as the QFP10 or the like, as shown in FIG. 7 and FIG. 8.

In that case, the T-TFBGA 8 can be packaged by the same solder reflow process that is the packaging process of the QFP10, that is, can be packaged mixedly with the QFP10 or the like.

According to the semiconductor device (T-TFBGA 8) of the first embodiment and its manufacturing method, the following operation and effects can be obtained.

Namely, since the dummy leads 2e are formed in the corner portions of the tape substrate 2 of the T-TFBGA 8 such that the lead pattern of the leads 2a is symmetrically arranged with the diagonal lines 5 of the tape substrate 2, when stress such as a thermal stress or the like is applied to the corner portions of the tape substrate 2 in a temperature cycle test, this stress applied to the corner portions can be dispersed nearly uniformly to both sides of the diagonal lines 5 of the tape substrate 2.

This can prevent the stress form concentrating on the specific regions in the corner portions of the tape substrate 2 in the temperature cycle test and can prevent a break in the leads 2a near the corner portions of the tape substrate 2.

As a result, this can improve the reliability of the semiconductor device of the Fan-Out type using the tape substrate 2, that is, the T-TFBGA 8.

(Second Embodiment)

FIG. 9 is a plan view showing an example of a lead pattern in the tape substrate of a semiconductor device of a second embodiment in accordance with the present invention. FIG. 10 is a partial enlarged plan view showing the detailed structure of a portion C in FIG. 9.

The semiconductor device of the second embodiment is a T-TFBGA 11 of the same Fan-Out type as is the type of the first embodiment and is different from the T-TFBGA 8 of the first embodiment in that dummy leads 2e are mounted in the vacant regions 2g where the leads 2a of the tape substrate 2 are not mounted, as shown in FIG. 9 and FIG. 10.

In other words, since the leads 2a are not mounted in the corner portions of the tape substrate 2 and the dummy leads 2e are mounted in the vacant regions 2g of the corner portions such that the leads 2a and the dummy leads 2e are arranged in good balance, the stress applied to the corner portions are dispersed to the whole areas of the corner portions and the strength of the corner portions in the tape substrate 2 is enhanced.

The other constitution of the T-TFBGA 11 of the second embodiment is the same as that of the T-TFBGA 8 described in the first embodiment and its description will not be repeated.

As for the manufacturing method of the T-TFBGA 11 of the second embodiment, the T-TFBGA 11 of the second embodiment can be manufactured by the same manufacturing method as is used for manufacturing the T-TFBGA 8 of the first embodiment by the use of a tape substrate 2 having dummy leads 2e in the vacant regions 2g in the corner portions where leads 2a, as shown in FIG. 9, are not mounted.

Further, as for the packaging of the T-TFBGA 11, the T-TFBGA 11 can be mixedly packaged by the same solder reflow packaging process that is used for packaging the semiconductor device of the other surface packaging type (for example, the QFP10 shown in FIG. 7 and FIG. 8) as is the case with the T-TFBGA 8 of the first embodiment.

According to the T-TFBGA 11 of the second embodiment, since the dummy leads 2e are formed in the vacant regions 2g in the corner portions in the tape substrate 2 where leads 2a are not formed, the strength of the corner portions of the tape substrate 2 can be enhanced. As a result, this can prevent a break in the leads 2a in the corner portions of the tape substrate 2 in the temperature cycle test.

This can improve the reliability of the T-TFBGA 11 of the Fan-Out type.

Also, since the strength of the corner portions of the tape substrate 2 can be enhanced, the tape substrate 2 can be prevented from being warped or deformed and therefore the flatness of the tape substrate 2 in the T-TFBGA 11 can be improved.

Therefore, the packaging performance of the T-TFBGA 11 can be improved.

Also, since the dummy leads 2e are formed in the vacant regions 2g in the corner portions of the tape substrate 2 where the leads 2a are not formed, it is possible to disperse stress such as thermal stress and the like to the whole area of the corner portions of the tape substrate 2, said stress being applied to the corner portions of the tape substrate 2 during the temperature cycle test or the like.

This can prevent the stress from being concentrated on the vacant regions 2g in the corner portions of the tape substrate 2 where the leads 2a are not formed and hence can prevent a break in the leads 2a formed near the vacant regions 2g. As a result, this can improve the reliability of the T-TFBGA 11.

(Preferred Embodiment 3)

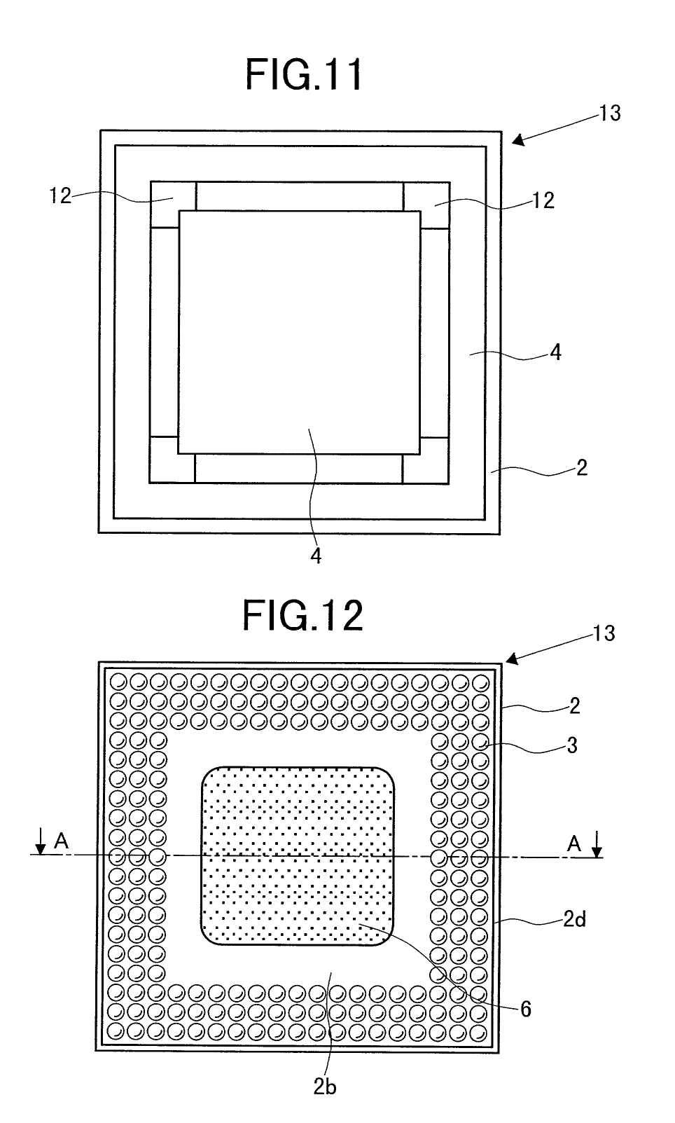

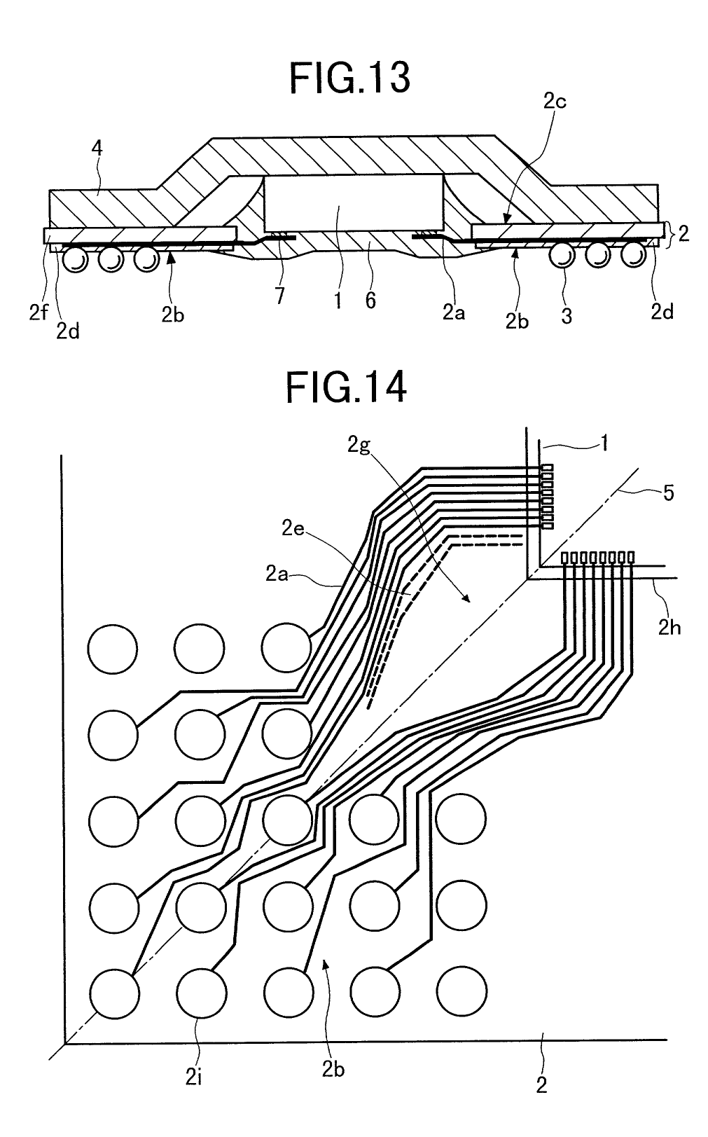

FIG. 11 is a plan view showing an example of the structure of a semiconductor device in accordance with a third embodiment of the present invention. FIG. 12 is a bottom view showing the structure of the semiconductor device shown in FIG. 11. FIG. 13 is a sectional view showing the structure of the cross section taken along the line A-A in FIG. 12. FIG. 14 is a partial enlarged plan view showing an example of a lead pattern of the tape substrate of the semiconductor device shown in FIG. 11 to FIG. 13.

The semiconductor device of the third embodiment is a T-HBGA (Tape-type Heat-sink BGA) or T-HFBGA (Tape-type Heat-sink Fine-pitch BGA), which is one kind of T-FBGA or T-TFBGA described in the first embodiment or the second embodiment. The semiconductor device of the third embodiment is a semiconductor package of a fine-pitch type having many pins for the size of a chip such as a microcomputer, an ASIC, or the like, and has 300 pins or more, for example, 352 pins, 400 pins or 600 pins.

As shown in FIG. 11 and FIG. 13, the semiconductor device 13 of the third embodiment has a tape substrate 2, which is square in a plan view and which has a square opening for arranging a semiconductor chip 1 in its center; and a reinforcing member 4 which is mounted on the back face 2c of the tape substrate 2 and which covers the back face of the semiconductor chip 1 from above the back face 2c. As shown in FIG. 12 and FIG. 13, a plurality of rows of solder balls 3 are mounted on the external terminal mounting face 2b of the tape substrate 2 such that they surround the semiconductor chip 1 as is the case with the first embodiment. The semiconductor chip 1 is covered with a sealing portion 6 formed of resin. Further, a solder resist 2d is formed on the surface of the external terminal mounting face 2b of the square tape substrate 2 except for the solder balls 3 and the ball lands 2i under the solder balls 3. In other words, the leads 2a are covered with the solder resist 2d.

As shown in FIG. 14, the dummy leads 2e are formed in and in the vicinity of the corner portions of the external terminal mounting face 2b of the tape substrate 2 such that a lead pattern is symmetrically arranged with respect to the diagonal line 5 of the tape substrate 2. The one ends of the dummy leads 2e are terminated on the tape substrate 2 without projecting into the opening 2h of the tape substrate 2 and the other ends are terminated without being bonded to the ball lands 2i.

In this way, the lead pattern composed of the leads 2a AND the dummy leads 2e is symmetrically arranged with respect to the diagonal lines 5 of the tape substrate 2 in the external terminal mounting face 2b side and hence the thermal stress generated when a temperature cycle test is conducted or the semiconductor device is packaged on a wiring board is not applied intensively to the corner portions and their vicinities of the tape substrate but it is dispersed to the corner portions and their vicinities. As a result, this can prevent a break in the leads 2a formed in the corner portions and their vicinities of the tape substrate 2 and can improve the reliability of the T-HBGA.

Further, the semiconductor device of the third embodiment has slits 12 in some portions of the reinforcing member 4, as shown in FIG. 11. These slits 12 prevent the problems that air or gas in the region surrounded by the tape substrate 2, the reinforcing member 4, and the semiconductor chip 1 is expanded to separate the reinforcing member 4 from the tape substrate 2 or to break the leads 2a of the tape substrate 2; that is, these slits 12 are openings for relieving the gas.

(Preferred Embodiment 4)

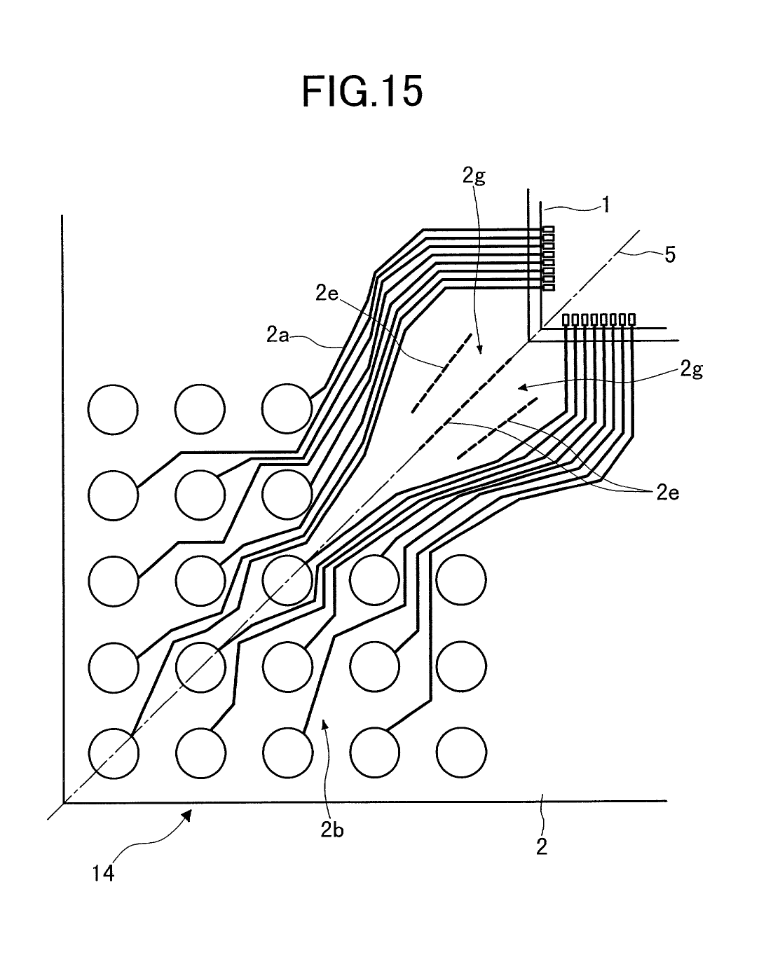

FIG. 15 is a partial enlarged plan view showing an example of a lead pattern in a tape substrate of a semiconductor device in accordance with a fourth embodiment of the present invention.

The semiconductor device 14 of the fourth embodiment is the same T-HBGA or T-HFBGA as the third embodiment and is different from the third embodiment in that a plurality of dummy leads 2e are formed in the vacant regions 2g in the corner portions and their vicinities of the external terminal mounting face 2b of the tape substrate 2 where the leads 2a are not formed, as shown in FIG. 15. The plurality of dummy leads 2e are symmetrically arranged with respect to the diagonal lines 5 of the tape substrate 2 and are formed also along the diagonal lines 5.

In this way, since the dummy leads 2e are formed in the vacant regions 2g where the leads 2a are not formed, a lead pattern including the dummy leads 2e and the leads 2a are arranged in good balance with respect to the diagonal lines 5 in the corner portions and their vicinities of the external terminal mounting face 2b side of the tape substrate 2, which can improve the strength of the corner portions and their vicinities of the tape substrate 2.

As a result, this can disperse the thermal stress generated when the temperature cycle test is conducted or the semiconductor device is packaged on the wiring board by reflow soldering or the like to the whole area of the corner portions and their vicinities and hence can prevent a break in leads 2a.

In this connection, in the fourth embodiment, if the lead pattern is arranged in good balance with respect to the diagonal lines 5 of the tape substrate 2, the dummy leads 2e are not necessarily formed along the diagonal lines 5. However, if the dummy leads 2e are formed along the diagonal lines 5, they can further enhance the strength of the corner portions and their vicinities of the tape substrate 2 as compared with the case where the dummy leads 2e are not formed along the diagonal lines 5.

Up to this point, while the invention made by the present inventors have been described based on the first, second, third and fourth embodiments, it is not intended to limit the present invention to the first, second, third and fourth embodiments. On the contrary, needless to say, the present invention may be further modified within the spirit and scope of the present invention as defined by the appended claims.

For example, while the case where the tape substrate 2 is prepared and then the reinforcing member 4 is mounted before the inner lead bonding process has been described in the manufacturing method of the semiconductor device (T-TFBGA 8, 11) in the first and second embodiments, as for the mounting procedure of the reinforcing member 4, the reinforcing member 4 may be mounted between the resin sealing process and the solder ball mounting process, or the semiconductor device may be delivered (prepared) by using the tape substrate 2 on which the reinforcing member 4 is previously mounted.

Also, while the case where individual semiconductor devices are manufactured by using a long multiple film tape including a plurality of tape substrates 2 linked to each other has been described in the first and second embodiments, the individual semiconductor device may be manufactured by using the tape substrate 2 which is previously cut as an individual semiconductor.

Also, while the case where the dummy leads 2e are formed in all the four corner portions of the tape substrate 2 has been described in the first, second, third and fourth embodiments, the dummy leads 2e are not necessarily formed in all the corner portions of the tape substrate 2.

However, in the tape substrate 2 if a corner has a vacant space where the leads 2a can be formed, the dummy leads 2e needs to be formed therein. As a result, it is essential only that the leads 2a or the dummy leads 2e are formed so as to eliminate the vacant space in all the corner portions of the tape substrate 2.

This can disperse stress in all the corner portions of the tape substrate 2.

Also, the method of arranging the dummy leads 2e in the corner portions of the tape substrate 2 may be a combination of the methods described in the first, second, third and fourth embodiments.

In other words, in the corner portions of the tape substrate 2, the dummy leads 2e are formed such that the leads 2a are symmetrically arranged with respect to the diagonal lines 5 of the tape substrate 2 and further the dummy leads 2e are formed also in the vacant regions 2g in the corner portions as shown in FIG. 9 and FIG. 10. In this case, the result is that the dummy leads 2e are formed in all the vacant regions 2g of the corner portions of the tape substrate 2 and the leads 2a are arranged symmetrically with respect to the diagonal lines 5.

This can enhance the strength of the corner portions of the tape substrate 2 and can disperse the stress applied to the corner portions of the tape substrate 2 to the whole area of the corner portions.

Also, while the case where the semiconductor device is the T-TFBGA 8 or 11 of the fine-pitch type and the Fan-Out type has been described in the first and second embodiments; it is essential only that the semiconductor device is formed of the tape substrate 2 and has the external terminals at least on the outside periphery of the semiconductor chip 1, and then the semiconductor device is not necessarily a semiconductor device of the Fan-Out type but it may be a semiconductor device of the Fan-In/Out type and further may be the other semiconductor device such as T-TBGA, LGA (Land Grid Array) or the like.

The advantages produced by the typical invention among the inventions disclosed in the present application will be described in brief as follows.

(1) According to the present invention, in the tape substrate of a semiconductor device, since dummy leads are formed in the corner portions such that leads are symmetrically arranged with respect to the diagonal lines of the tape substrate, the stress applied to the corner portions of the tape substrate can nearly uniformly dispersed to both sides with respect to the diagonal lines. This can prevent a break in the leads in the corner portions of the tape substrate. As a result, this can improve the reliability of the semiconductor device.

(2) According to the present invention, in the tape substrate of a semiconductor device, since dummy leads are formed in the vacant regions of the corner portions where leads are not formed, they can enhance the strength of the corner portions of the tape substrate. This can prevent a break in the leads in the corner portions of the tape substrate. As a result, this can improve the reliability of the semiconductor device. (3) According to the above (2), since the strength of the corner portions of the tape substrate can be enhanced, the tape substrate can be prevented from being warped or deformed. This can improve the flatness of the tape substrate. Therefore, this can improve the performance of packaging the semiconductor device.

What is claimed is:

1. A semiconductor device comprising:
a tape substrate which supports a semiconductor chip, said chip having surface electrodes, said tape substrate being provided with a plurality of leads corresponding to the surface electrodes of the semiconductor chip and bonded thereto, and with dummy leads formed in vacant regions in corner portions of the tape substrate where the leads are not formed;
conductive members for bonding the surface electrodes of the semiconductor chip to the leads of the tape substrate; and
a plurality of external terminals arranged on an outside periphery of the semiconductor chip and mounted on the tape substrate.

2. A semiconductor device comprising:
a tape substrate which supports a semiconductor chip, said chip having surface electrodes, said tape substrate being provided with a plurality of leads correspond to the surface electrodes of the semiconductor chip and bonded thereto, and with dummy leads formed in corner portions of the tape substrate such that the dummy leads are symmetrically arranged with respect to a diagonal line of the tape substrate;
conductive members for bonding the surface electrodes of the semiconductor chip to the leads of the tape substrate; and
a plurality of external terminals arranged on an outside periphery of the semiconductor chip and mounted on the tape substrate.

3. A method of manufacturing a semiconductor device, comprising the steps of:
preparing a tape substrate having leads and dummy leads, said leads corresponding to surface electrodes of a semiconductor chip and capable of being bonded thereto, and said dummy leads being formed in vacant regions in corner portions of the tape substrate where the leads are not formed;
bonding the surface electrodes of the semiconductor chip to the corresponding leads of the tape substrate by conductive parts to support the semiconductor chip by the tape substrate; and
mounting a plurality of external terminals on an outside periphery of the semiconductor chip in an external terminal mounting face of the tape substrate,
wherein the dummy leads can enhance strength of the corner portions of the tape substrate.

4. A method of manufacturing a semiconductor device, comprising the steps of:
preparing a tape substrate having leads and dummy leads, said leads corresponding to surface electrodes of a semiconductor chip and capable of being bonded thereto, and said dummy leads being formed in corner portions on the tape substrate such that the leads are symmetrically arranged with respect to a diagonal line of the tape substrate;
bonding the surface electrodes of the semiconductor chip to the corresponding leads of the tape substrate by conductive parts to support the semiconductor chip by the tape substrate; and
mounting a plurality of external terminals on an outside periphery of the semiconductor chip in an external terminal mounting face of the tape substrate,
wherein the dummy leads can disperse stress applied to corner portions of the tape substrate.

5. A method of manufacturing a semiconductor device, comprising the steps of:
preparing a tape substrate having leads and dummy leads, said leads corresponding to surface electrodes of a semiconductor chip and capable of being bonded thereto, and said dummy leads being formed in vacant regions in corner portions of the tape substrate where the leads are not formed and being formed in the corner portions of the tape substrate such that the leads are symmetrically arranged with respect to a diagonal line of the tape substrate;
bonding the surface electrodes of the semiconductor chip to the corresponding leads of the tape substrate by conductive parts to support the semiconductor chip by the tape substrate; and
mounting a plurality of external terminals on the outside periphery of the semiconductor chip in the external terminal mounting face of the tape substrate,
wherein the dummy leads can enhance strength of the corner portions of the tape substrate and can disperse stress applied to the corner portions of the tape substrate.

6. A semiconductor device comprising:
a square tape substrate; an opening provided at a center of the tape substrate; a semiconductor chip arranged at the opening; a plurality of leads projecting from the tape substrate and bonded to a plurality of electrodes on a surface of the semiconductor chip; and a plurality of external terminals arranged on the tape substrate and bonded to the plurality of leads, respectively;
wherein the tape substrate has an external terminal mounting face having corner portions, and dummy leads are formed on the external terminal mounting face in the corner portions and vicinities thereto; and
a lead pattern constituted by the dummy leads and the plurality of leads is symmetrically arranged with respect to a diagonal line of the tape substrate.

7. A semiconductor device according to claim 6, wherein the opening of the square tape substrate is shaped like a square and the plurality of leads are extended to the opening and are bonded to the plurality of electrodes on the surface of the semiconductor device.

8. A semiconductor device according to claim 6, wherein the tape substrate comprises a film-shaped base material; a plurality of leads formed on one main surface of the base material; a solder resist covering the plurality of leads; and further a reinforcing member mounted on the other main surface opposed to the one main surface of the base material such that it surrounds the semiconductor chip.

9. A semiconductor device according to claim 6, wherein the plurality of external terminals are a plurality of solder balls.

10. A semiconductor device comprising:
a square tape substrate; an opening provided at a center of the tape substrate; a semiconductor chip arranged at the opening; a plurality of leads projecting from the tape substrate and bonded to a plurality of electrodes on a surface of the semiconductor chip; and a plurality of external terminals arranged on the tape substrate and bonded to the plurality of leads, respectively;
wherein the tape substrate has an external terminal mounting face having corner portions, and a plurality of dummy leads are formed symmetrically with respect to a diagonal line of the tape substrate in the corner portions and vicinities thereto.

11. A semiconductor device according to claim 10, wherein a part of the plurality of dummy leads are formed along the diagonal lines of the tape substrate.

12. A semiconductor device according to claim 10, wherein the opening is shaped like a square and wherein the plurality of dummy leads are extended to the opening and are bonded to a plurality of electrodes on the surface of the semiconductor chip.

13. A semiconductor device according to claim 10, wherein the tape substrate comprises a film-shaped base material, a plurality of leads formed on one main surface of the base material, a solder resist covering the plurality of leads, and further a reinforcing member mounted on the other main surface opposed to the one main surface of the base material such that it surrounds the semiconductor chip.
